(19) United States
(12) Patent Application Publication
(10) Pub. No.: US 2007/0269612 A1
(43) Pub. Date: Nov. 22, 2007

(54) Method and an Apparatus for Applying a Coating on a Substrate

(75) Inventors: Martin D. Bijker, Helmond (NL); Roland C.M. Bosch, Eindhoven (NL); Franciscus C. Dings, Veldhoven (NL)

Correspondence Address: PILLSBURY WINTHROP SHAW PITTMAN, LLP;Eric S. Cherry - Docketing Supervisor, P.O. BOX 10500, MCLEAN, VA, 22102, US

(73) Assignee: OTB Group B.V., Eindhoven (NL)

(21) Appl. No.: 10/566,153

(22) PCT Filed: Aug. 12, 2004
(86) PCT No.: PCT/NL04/00566

§ 371 Date: Feb. 20, 2007

(30) Foreign Application Priority Data
Aug. 13, 2003 (NL) 1024101

(51) Int. Cl. H05H 1/24; C23C 16/00

(52) U.S. Cl. 427/569; 118/719

(57) ABSTRACT

A method and apparatus for applying a coating on a substrate, wherein, opposite the substrate, at least two expanding thermal plasma (ETP) sources are arranged which provide the substrate with a coating, wherein the substrate is located in a process room in which the pressure is lower than the pressure, prevailing in the ETP sources, of a carrier gas which is introduced into the process room via the sources and which forms the expanding plasma, wherein the coating provided by each source has a layer thickness according to a certain deposition profile, for instance a Gaussian deposition profile, and wherein different process parameters are chosen such that, after the coating process, the addition of the deposition profiles results in a substantially uniform layer thickness of the coating on a relevant part of the substrate. Preferably, the distance between sources producing plasma at the same time is chosen and/or settable such that the expanding plasmas substantially do not influence each other.

The invention relates to a method and an apparatus for applying a coating on a substrate.

More particularly, the invention relates to applying, by means of a number of expanding thermal plasma sources, a coating on a substrate having a considerable surface. The surface of the substrate is then so large that it cannot be covered by a single source. From the state of the art, various proposals are known to coat substrates having a large surface by means of ETP sources. In this connection, for instance, reference is made to EP-A-0 297 637, in which it is clearly indicated that multiple sources can be arranged in one process chamber. Further, reference is made to DE-196 10 015 A1, in which the use of multiple ETP sources in a single process room for covering a moving substrate band is disclosed. U.S. Pat. No. 6,397,776 B1 also describes an apparatus for depositing a coating on a large surface by means of multiple ETP sources. However, in none of these publications, is it indicated in what manner a uniform layer thickness of the coating over a relevant part of the substrate can be obtained. For instance, U.S. Pat. No. 6,397,776 B1 ignores the fact that the plasma plumes of the ETP sources will interfere with each other and will push each other away. As a result of this phenomenon, interference-like deposition patterns have been found to arise between the sources, so that, there, the layer thickness is not uniform. The tables of tests included in the respective publication show considerable layer thickness differences.

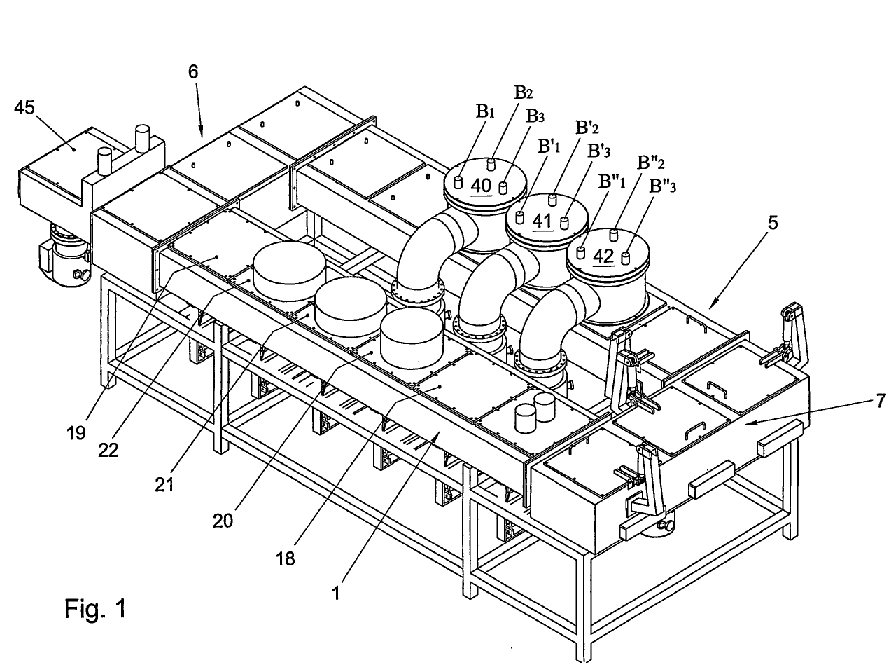

As FIG. 1 of DE-196 10 015 A1 clearly shows, the distance between the aligned sources there is such that the coating tracks obtained in this manner do not touch each other. From this, it can be derived that the plasma plumes in this arrangement do not interfere with each other.

However, it is a problem to achieve that the parts of the passing substrate not yet covered with coating are completely and uniformly covered with a coating by a second row of sources. In the manner as shown FIG. 1, where some parts of the substrate are still completely uncovered after passing the first row of sources, it is impossible to obtain a uniform layer thickness.

Temperature differences over the surface of the substrate can also result in differences in layer thickness of the coating applied.

The invention contemplates a method and an apparatus by means of which such a uniform layer thickness can actually be obtained.

For this purpose, the invention provides a method for applying a coating on a substrate, in which, opposite the substrate, at least two expanding thermal plasma (ETP) sources are arranged which provide the substrate with a coating, the substrate being located in a process room in which the pressure is lower than the pressure, prevailing in the ETP sources, of a carrier gas which is introduced into the process room via the sources and which forms the expanding plasma, the coating applied by each source having a layer thickness according to a certain deposition profile, for instance a Gaussian deposition profile, and different process parameters being chosen such that, after the coating process, the addition of the deposition profiles results in a substantially uniform layer thickness of the coating on a relevant part of the substrate.

The invention further provides an apparatus for carrying out the method according to the invention, which apparatus is provided with a process chamber enclosing a process room, pumping means for creating an underpressure in the process room, at least two expanding thermal plasma (ETP) sources through which a carrier gas is supplied to the process room under a higher pressure than the pressure prevailing in the process room, thereby forming an expanding plasma, and a substrate holder for carrying at least one substrate, the coating applied by each source having a layer thickness according to a certain deposition profile, for instance a Gaussian deposition profile, and different process parameters being settable such that, after the coating process, the addition of the deposition profiles results in a substantially uniform layer thickness of the coating on a relevant part of the at least one substrate.

The deposition profile—for a source having a circular outflow opening, the deposition profile will generally be a circularly symmetric Gaussian deposition profile—provides the person who is to set the method with information regarding the layer thickness composition of a single source. Such deposition profiles depend on various process parameters such as for instance the pressure of the carrier gas in the source, the pressure prevailing in the process chamber, the arc flow prevailing in the source, the design of the source itself, the distance from the source to the substrate and similar quantities. For a single source, the various deposition profiles can be determined for different process parameters. When more than one source is used, a substantially uniform layer thickness will be obtained when the addition of the different deposition profiles after the deposition process on the substrate has resulted in a flat profile over the relevant part of the surface of the substrate. As indicated hereinabove, temperature differences of the substrate itself can also result in differences in layer thickness of the coating. Other process conditions can also result in layer thickness differences which are difficult to predict theoretically.

According to a further elaboration of the invention, these layer thickness differences which cannot well be predicted can be measured over the surface of the substrate of the layer obtained after the coating process, after which the process parameters are adjusted for reducing the thickness variations observed.

According to a further elaboration of the invention, the measurement of the layer thickness can take place in-line and automatically and the adjustment of the process parameters can also take place automatically. However, an off-line measurement by an operator and the manual adjustment of the process parameters by this operator also fall within the scope of the present invention.

The measurement can take place directly by means of a layer thickness gauge, off line or in-line (automatically).

Further, indirect measurements are possible, which have the additional advantage that the risk of damage of the layer is minimal. Indirect measurements can be optical measurements which can be based on transmission or reflection. For substantially transparent objects, such as window screens, the transmission of light through the object provides information about the layer thickness and about the uniformity or homogeneity of the layer over the surface. Further, information can be obtained about the optical characteristics of the layer which has been applied. For non-transparent objects, such as e.g. solar cells, the color of the cell provides information about the layer thickness. By scanning the surface of the solar cell with light having a particular wave length, the homogeneity of the color over the surface can be determined.

For layers which are capable of conducting electricity, a resistance measurement between two or more points on the surface can provide information about the uniformity or homogeneity of the layer thickness.

Because the substrate is, mostly, heated during the deposition process, a temperature measurement of the substrate can also provide information about the uniformity or homogeneity of the layer thickness.

According to a further elaboration of the invention, it is particularly advantageous when one of the process parameters to be chosen is the distance between sources producing plasma plumes at the same time, this distance being chosen or set such that the expanding plasmas substantially do not influence each other, in the sense that the shapes of the plasma plumes substantially correspond to the shape of a single plasma plume in a corresponding process chamber under otherwise corresponding process conditions. As a result of the fact that the distance of the ETP sources switched on at the same time is so great that the expanding plasmas do not influence each other, the above-described interference-like deposition patterns resulting from interaction between sources arranged too close to each other do not occur. The deposition profiles thus remain separated from each other so that the theoretical addition made for obtaining a uniform or flat deposition profile actually results in a uniform layer thickness in practice.

According to a further elaboration of the invention, with a stationary substrate, the most neighboring sources can be switched on in alternation. Then, the sources can be actually arranged closely to each other, but the most neighboring sources are prevented from being switched on at the same time, so that it is thus achieved that the plasma plumes of the most neighboring sources cannot influence each other because they are never present at the same time. Of course, with such a batch production, first, coating will be formed in which peaks and holes are present. When, subsequently, the neighboring sources which were first switched off are switched on and the sources first switched on are switched off, the holes in the coating will gradually be filled and, thus, a substantially uniform layer thickness can be obtained without interference-like phenomena occurring therein.

According to an alternative further elaboration of the method according to the invention, the substrate is moved relative to the sources in a conveying direction, while all sources are switched on at the same time, the mutual distance between neighboring sources being chosen such that the expanding plasmas substantially do not influence each other, in the sense that the shapes of the plasma plumes substantially correspond to the shape of a single plasma plume in a corresponding process chamber, while, viewed in the conveying direction, at least one of the sources is arranged behind or in front of the other sources, the positions of the sources in a direction transverse to the conveying direction being such that the projection position of one of the three sources is located in the middle between the projection positions of the other two sources.

According to a further elaboration, a practical design in which a minimal use of space in a longitudinal direction is required is obtained using a method in which three sources are provided which are located on the angular points of an imaginary triangle, with two angular points being located on an imaginary line extending transversely across the conveying direction and with the third angular point being at equal distances from the two other angular points.

According to a further elaboration of the invention, the apparatus can be characterized in that the sources are mounted slidably relative to the process chamber in a direction transverse to the conveying direction. By means of such an apparatus, the uniform layer thickness can simply be obtained by taking a number of samples, allowing, when a variation occurs in the layer thickness viewed transversely to the conveying direction of the substrate, the distance between the sources to be increased or decreased. As already indicated hereinabove, the samples can also be taken in-line and automatically and the adjustment of the distance between the sources can also be taken automatically on the basis of the layer thickness measurements taken in-line.

Optionally, the apparatus can be characterized in that sources are tiltably mounted on the process chamber, such that the outflow angle of the various plasma plumes relative to the substrate can be varied.

According to a further elaboration, the apparatus is further provided with a control for varying, preferably independently of one another, the arc flow, the pressure of the carrier gas in the various ETP sources, and/or the pressure in the process chamber. The invention will be further elucidated on the basis of an exemplary embodiment of the apparatus with reference to the drawings, in which:

FIG. 1 shows a perspective view of an assembly for treating substrates;

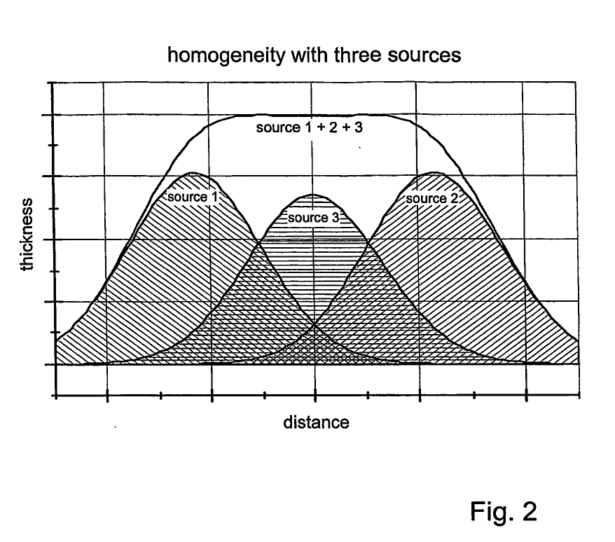

FIG. 2 shows the deposition profiles of three sources arranged in a triangle configuration;

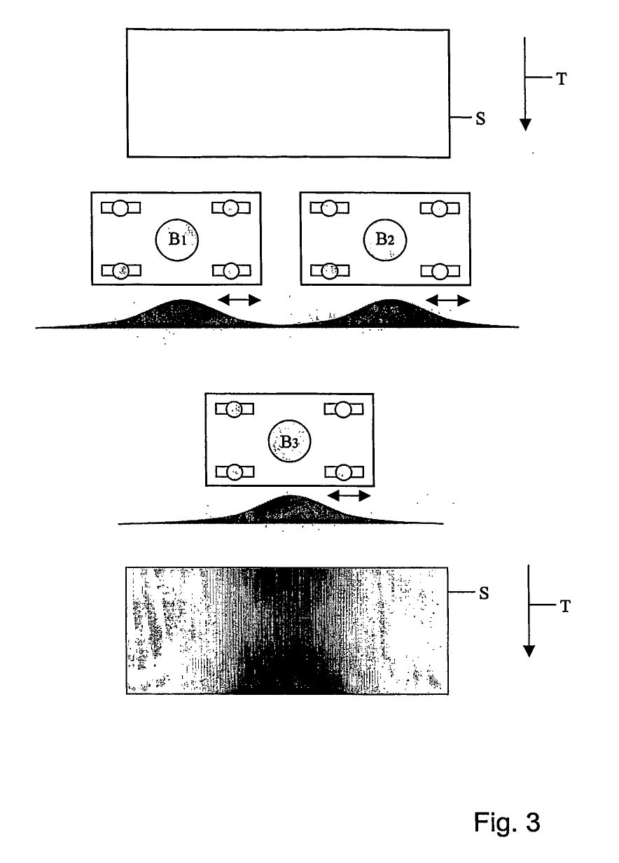

FIG. 3 shows a top plan view of three slidably arranged sources;

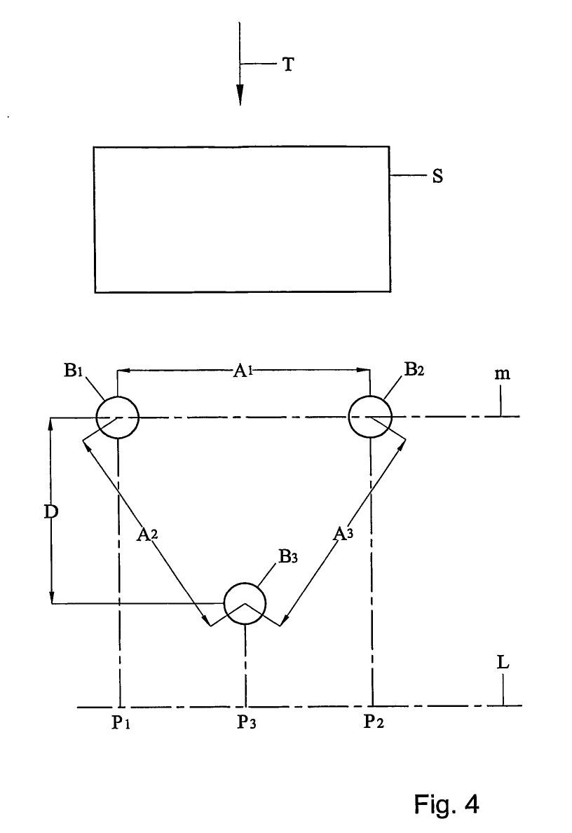

FIG. 4 shows a diagrammatic top plan view of three sources arranged in a triangle configuration;

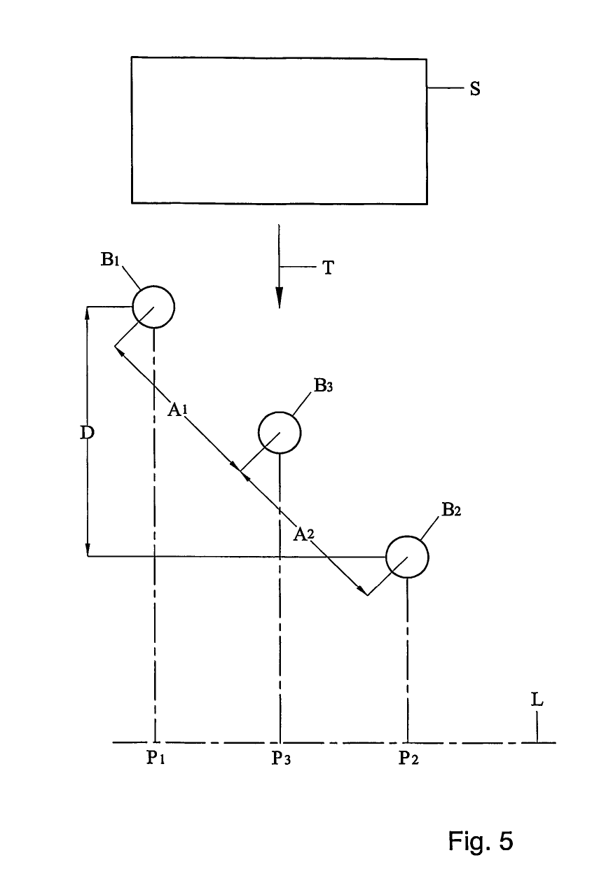

FIG. 5 shows a diagrammatic top plan view of three sources arranged in a line configuration; and

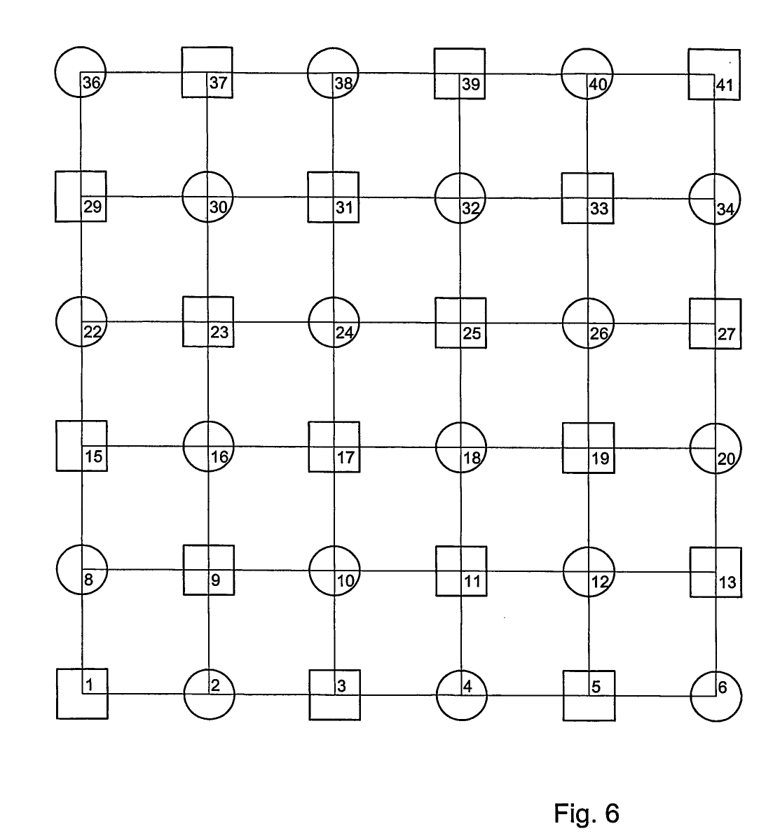

FIG. 6 shows a diagrammatic top plan view of a number of sources which can be switched on in alternation.

FIG. 1 shows a perspective view of an assembly for treating substrates, which assembly is described in European patent application 03 076554.9 whose contents should considered inserted here. The assembly shown is provided with a number of process chambers 40, 41, 42 and with a conveying system, extending in a conveying housing, provided with carriers mobile over rails by means of which a substrate which is to be subjected to a coating treatment can be moved along process chambers 40, 41, 42. As described in the European patent application mentioned, in the process chambers, a PECVD process can take place in which use is made of, for instance, expanding thermal plasma sources. In contrast to the European patent application mentioned, FIG. 1 of the present application shows that each process chamber is provided with three PECVD sources, more particularly ETP sources.

In order to obtain a good uniform layer thickness on the passing substrate, it is important that the different process parameters in a process chamber are chosen such that, after the coating process, the addition of the deposition profiles results in a substantially uniform layer thickness of the coating on a relevant part of the substrate. Here, one of the process parameters is the distance between the ETP sources producing plasma plumes at the same time, this distance being chosen and/or set such that the expanding plasmas substantially do not influence each other, in the sense that the shapes of the plasma plumes substantially correspond to the shape of a single plasma plume in a corresponding process chamber under otherwise corresponding process conditions.

FIG. 2 shows the shape of a deposition profile of three sources. The sources have a circular plasma outflow opening, so that the resulting deposition profile on a passing substrate is a Gaussian profile. It is clearly visible that, with a proper positioning of the sources and with a right shape of the deposition profile, a resulting deposition profile can be obtained which results in a uniform layer thickness on a relevant part of the substrate. Here, the width of the deposition profile can, for instance, be influenced by the arc flow used in the respective source. Further, the shape of the deposition profile can be influenced by the pressure of the carrier gas in the source and the pressure prevailing in the process chamber. Preferably, the pressure of the carrier gas in the source is controllable per source, more specifically independently of each other. Although some overlap between the deposition profiles of sources B1 and B2 is present, this overlap is so slight that the plasma plumes of the sources B1 and B2 do not push each other away or influence each other in such a manner that interference-like patterns in the layer thickness composition occur. The slight overlap between the deposition profiles of sources B1 and B2 actually contributes to the uniformity of the resulting layer thickness, which appears from the addition of the deposition profiles.

FIG. 3 shows a top plan view of the arrangement of three ETP sources, at least of the source plates on which these sources are mounted and a substrate located upstream of these sources and a substrate located downstream of these sources which is covered with a coating. Further, per source, the respective deposition profile is shown. It is clearly visible that the source plates are arranged slidably in a direction transverse to the conveying direction T, so that the distance between the various deposition profiles can be set in order to obtain a uniform layer thickness of the coating on the substrate. Optionally, the sources can also be tiltably arranged. As already indicated hereinabove, downstream of the sources, a measuring device can be arranged by means of which the layer thickness of the coating just applied can be measured. Depending on the measurement results, the positions of the sources and, optionally, other process parameters, can be adjusted automatically or manually. It will be clear that, in a variant in which the substrate does not move, the measuring device is arranged in the process chamber for observing the layer thickness on the different parts of the substrate.

FIGS. 4 and 5 further clarify the terminology of particularly claims 4 and 13. Both Figures show a set of three sources B1, B2, B3, and a substrate S moving in a conveying direction T below the sources B1-B3. In the angular points of an imaginary triangle. Two angular points are located on an imaginary line M extending transversely to the conveying direction T. The third angular point, on which source B3 is located, is at equal distances A2, A3 from the two other angular points. It holds true for both FIG. 4 and FIG. 5 that one of the two sources—in FIG. 4 source B3 and in FIG. 5 source B2—is arranged behind the other sources. The positions of the sources B1, B2, B3 in a direction transverse to the conveying direction are such that the neighboring projections P1, P2, P3 of the three sources on an imaginary line L extending transversely to the conveying direction T are such that the projection position of one of the three sources P3 is located in the middle between the projection positions P1, P2 of the other two sources. The advantage of the exemplary embodiment of FIG. 4 compared to that of FIG. 5 is that the required conveying length D to apply the respective coating is minimal.

FIG. 6 shows an exemplary embodiment of an arrangement of a number of sources 1-41, which sources are located on the angular points of an imaginary grid. The respective arrangement is particularly intended for coating a stationary substrate located opposite the sources. If all sources were switched on at the same time, their plasma plumes would influence each other, which results in interference-like patterns in the layer thickness of the coating. By first switching on the sources designated by even numbers and then switching them off, after which the sources with the odd numbers are switched on, it is achieved that, first, a coating is formed having peaks and holes, with the holes being gradually filled in the second deposition step, so that the final result is a coating with a substantially uniform layer thickness. In other words, the neighboring sources are switched on in alternation, with this terminology also comprising the variant that only two steps are passed through, viz., first, switching on the odd sources (designated by squares for reasons of clarity) and, in a second step, switching on the even sources (designated by circles for reasons of clarity), in which second step, the odd sources are switched off.

It will be clear that the invention is not limited to the exemplary embodiments described but that various modifications are possible within the scope of the invention.

1. A method for applying a coating on a substrate, comprising:
a coating process including arranging, opposite the substrate, at least two expanding thermal plasma (ETP) sources which provide the substrate with a coating, wherein the substrate is located in a process room in which the pressure is lower than the pressure, prevailing in the ETP sources, of a carrier gas which is introduced into the process room via the sources and which forms the expanding plasma, wherein the coating provided by each source has a layer thickness according to a deposition profile, and
choosing different process parameters such that, after the coating process, addition of the deposition profile results in a substantially uniform layer thickness of the coating on a part of the substrate.

2. A method according to claim 1, further comprising:
measuring thickness variations over a surface of the substrate of the layer obtained after the coating process, and
subsequently, adjusting the process parameters for reducing the measured thickness variations.

3. A method according to claim 1, wherein one of the process parameters to be chosen is the distance between the at least two sources producing plasma plumes at the same time, the method further comprising:
setting the distance such that the expanding plasmas substantially do not influence each other, in the sense that the shapes of the plasma plumes substantially correspond to the shape of a single plasma plume in a corresponding process chamber under otherwise corresponding process conditions.

4. A method according to claim 3, wherein the substrate is stationary relative to the at least two sources and the at least two sources are switched on in alternation.

5. A method according to claim 3, wherein the substrate is moved relative to the at least two sources in a conveying direction, wherein the at least two sources are switched on at the same time and wherein the mutual distance between neighboring sources is chosen such that the expanding plasmas substantially do not influence each other, in the sense that the shapes of the plasma plumes substantially correspond to the shape of a single plasma plume in a corresponding process chamber, wherein at least one of the sources, viewed in the conveying direction, is arranged behind or in front of the other source and wherein the positions of the at least two sources in a direction transverse to the conveying direction are such that neighboring projections of three sources on an imaginary line extending transverse to the conveying direction are such that the projection position of one of the three sources is located in the middle between the other two sources.

6. A method according to claim 5, wherein three sources are provided which are located on angular points of an imaginary triangle, wherein two angular points are located on an imaginary line extending transversely to the conveying direction and wherein a third angular point is at equal distances from two other angular points.

7. A method according to claim 6, wherein one of the process parameters to be chosen, and to be varied depending on the other process parameters, for influencing the resulting layer thickness uniformity is an arc flow of each of the at least two ETP sources.

8. A method according to claim 7, wherein the arc flow of the source located on the third angular point is chosen to be lower than the arc flows of the other two sources.

9. A method according to claim 1, wherein one of the process parameters to be chosen, and to be varied depending on the other process parameters, for influencing the resulting layer thickness uniformity is the pressure of the carrier gas in the source.

10. A method according to claim 1, wherein one of the process parameters to be chosen, and to be varied depending on the other process parameters, for influencing the resulting layer thickness uniformity is a mutual positioning of the at least two sources.

11. A method according to claim 1, wherein one of the process parameters to be chosen, and to be varied depending on the other process parameters, for influencing the resulting layer thickness uniformity is an outflow angle of plasma plumes relative to the substrate.

12. A method according to claim 2, wherein the measurement of the layer thickness is performed automatically.

13. A method according to claim 2, wherein the measurement of the layer thickness is an optical measurement.

14. A method according to claim 2, wherein the measurement of the layer thickness is a resistance measurement between two or more points on the layer.

15. A method according to claim 2, wherein the measurement of the layer thickness is performed by a layer thickness gauge.

16. A method according to claim 2, wherein the measurement of the layer thickness is performed by a temperature measurement of the substrate surface.

17. An apparatus for for forming a coating on a substrate, comprising:
a process chamber enclosing a process room,
a pump configured to create an underpressure in the process room,
at least two expanding thermal plasma (ETP) sources through which a carrier gas is supplied to the process room, under a higher pressure than the pressure prevailing in the process room, thereby forming an expanding plasma in a coating process, and
a substrate holder configured to carry at least one substrate, wherein the coating applied by each source has a layer thickness according to a certain deposition profile, and wherein different process parameters are settable such that, after the coating process, the addition of the deposition profiles results in a substantially uniform layer thickness of the coating on a part of the at least one substrate.

18. An apparatus according to claim 17, wherein the apparatus is provided with a measuring device for measuring layer thickness variations over the surface of the substrate, wherein the apparatus is provided with a control for automatically setting at least a number of the process parameters to be set depending on the layer thickness variations measured by the measuring device.

19. An apparatus according to claim 17, wherein one of the process parameters to be set is the distance between sources producing plasma plumes at the same time, wherein this distance is settable such that the expanding plasmas substantially do not influence each other, in the sense that the shapes of the plasma plumes substantially correspond to the shape of a single plasma plume in a corresponding process chamber under otherwise corresponding process conditions.

20. An apparatus according to claim 19, wherein the substrate is stationary relative to the sources and wherein neighboring sources can be switched on in alternation.

21. An apparatus according to claim 19, wherein the substrate is arranged movably relative to the sources in a conveying direction, wherein all sources are switched on at the same time and wherein a mutual distance between neighboring sources is chosen such that the expanding plasmas substantially do not influence each other, in the sense that the shapes of the plasma plumes substantially correspond to the shape of a single plasma plume in a corresponding process chamber, wherein at least one of the sources, viewed in the conveying direction, is arranged behind or in front of the other sources and wherein the positions of the sources in a direction transverse to the conveying direction are such that the neighboring projections of three sources on an imaginary line extending transverse to the conveying direction are such that the projection position of one of the three sources is located in the middle between the other two sources.

22. An apparatus according to claim 21, wherein three sources are provided which are located on angular points of an imaginary triangle, wherein two angular points are located on an imaginary line extending transversely to the conveying direction and wherein the third angular point is at equal distances from the other two angular points.

23. An apparatus according to claim 22, wherein the sources are slidable relative to the process chamber.

24. An apparatus according to claim 23, wherein, when the substrate moves in the conveying direction relative to the sources, the sources are slidable in a direction transverse to the conveying direction.

25. An apparatus according to claim 17, wherein the sources are tiltably mounted on the process chamber, such that an angle of the plasma plumes relative to the substrate is variable.

26. An apparatus according to claim 17, further comprising a control configured to vary, the arc flows of the at least two ETP sources.

27. An apparatus according to claim 17, further comprising a control configured to vary the pressure of the carrier gas in the at least two ETP sources.

28. An apparatus according to claim 18, wherein the measurement of the layer thickness is performed automatically.

29. An apparatus according to claim 18, wherein the measuring device for measuring the layer thickness variations over the surface of the substrate comprises an optical measurement device.

30. An apparatus according to claim 18, wherein the measuring device for measuring the layer thickness variations over the surface of the substrate comprises an resistance measurement device for resistance measurement between two or more points on the layer.

31. An apparatus according to claim 18, wherein the measuring device for measuring the layer thickness variations over the surface of the substrate comprises a layer thickness gauge.

32. An apparatus according to claim 18, wherein the measuring device for measuring the layer thickness variations over the surface of the substrate comprises a temperature measurement device for temperature measurement of the substrate surface.

33. A method according to claim 1, wherein the deposition profile is a Gaussian deposition profile.

34. A method according to claim 1, wherein one of the process parameters to be chosen, and to be varied depending on the other process parameters, for influencing the resulting layer thickness uniformity is an arc flow of each of the at least two sources.

35. An apparatus according to claim 26, wherein the control is configured to vary the arc flows of the at least two sources independently of one another.

36. An apparatus according to claim 27, wherein the control is configured to vary the pressure of the carrier gas in the at least two sources independently of one another.

37. An apparatus according to claim 17, wherein the deposition profile is a Gaussian deposition profile.
